(19) United States
(12) Patent Application Publication
(10) Pub. No.: US 2025/0167068 A1
(43) Pub. Date: May 22, 2025

(54) MEMORY MODULE AND METHOD OF MANUFACTURING THE MEMORY MODULE

(71) Applicant: Samsung Electronics Co., Ltd., Suwon-si (KR)

(72) Inventors: Jinkyu YANG, Suwon-si (KR); Eunhye LEE, Suwon-si (KR); Doyoung JUNG, Suwon-si (KR); Hyunik HWANG, Suwon-si (KR)

(73) Assignee: Samsung Electronics Co., Ltd., Suwon-si (KR)

(21) Appl. No.: 18/927,154

(22) Filed: Oct. 25, 2024

(30) Foreign Application Priority Data
Nov. 20, 2023 (KR) 10-2023-0161043

(51) Int. Cl. H01L 23/367; H01L 21/48; H01L 23/00; H01L 25/00; H01L 25/065; H01L 25/18; H10B 80/00

(52) U.S. Cl. CPC H01L 23/3672; H01L 21/4853; H01L 21/4882; H01L 23/3675; H01L 24/16; H01L 25/0655; H01L 25/18; H01L 25/50; H10B 80/00; H01L 2224/16227; H01L 2924/1431; H01L 2924/1436; H01L 2924/14511

(57) ABSTRACT

A memory module may include a module substrate having a first surface and a second surface opposite to the first surface, the module substrate extending in a first direction; a plurality of electronic devices mounted on the first surface of the module substrate; a heat sink thermally coupled with the first surface of the module substrate, the heat sink including a base plate on the plurality of electronic devices and a plurality of heat dissipating fins on the base plate to be spaced apart from each other along the first direction, each of the plurality of heat dissipating fins extending in a second direction different from the first direction; and a plurality of adsorption work-pads respectively on a plurality of a central heat dissipating fins among the plurality of heat dissipating fins on a central region of the base plate, each of the plurality of adsorption work-pads having a hinge portion secured to an upper surface of the central heat dissipating fins and a folding portion extending from the hinge portion in the first direction and foldable by a certain angle relative to the hinge portion.

### PRIORITY STATEMENT

This application claims priority under 35 U.S.C. § 119 to Korean Patent Application Nos. 10-2023-0161043, filed on Nov. 20, 2023 in the Korean Intellectual Property Office (KIPO), the contents of which are herein incorporated by reference in their entirety.

### BACKGROUND

### 1. Field

Example embodiments relate to memory modules and methods of manufacturing the memory module. More particularly, example embodiments relate to memory modules including a heat sink providing a heat dissipating fins and methods of manufacturing the same.

### 2. Description of the Related Art

As a solid-state drive device SSD with high capacity and high bandwidth has been developed, a heat sink may be applied for the solid-state drive device to effectively dissipate heat inside the solid-state drive device to the outside. In order to improve heat dissipation performances of the heat sink, the heat sink may have a fin type structure where heat dissipating fins are disposed on a surface of the heat sink. However, in case that the heat sink has the fin type structure, because there is not enough space for adsorption on a surface of a product, automated assembly processes using a vacuum pick-up apparatus may be not possible, requiring an additional manual assembly process. Meanwhile, the heat sink may have a fin-flat type structure where additional contact surfaces for automated assembly are provided on a plurality of heat dissipating fins, but in the case of the fin-flat type structure, heat dissipation efficiency may decrease because air circulation for cooling is not smooth.

### SUMMARY

Example embodiments provide memory modules having a heat sink that is able to improve heat dissipation performances and enables automated assembly.

Example embodiments provide methods of manufacturing the memory module.

According to example embodiments, a memory module includes a module substrate having a first surface and a second surface opposite to the first surface, the module substrate extending in a first direction; a plurality of electronic devices mounted on the first surface of the module substrate; a heat sink thermally coupled with the first surface of the module substrate, the heat sink including a base plate on the plurality of electronic devices and a plurality of heat dissipating fins on the base plate to be spaced apart from each other along the first direction, each of the plurality of heat dissipating fins extending in a second direction different from the first direction; and a plurality of adsorption work-pads respectively on a plurality of a central heat dissipating fins among the plurality of heat dissipating fins on a central region of the base plate, each of the plurality of adsorption work-pads having a hinge portion secured to an upper surface of the central heat dissipating fins and a folding portion extending from the hinge portion in the first direction and foldable by a certain angle relative to the hinge portion.

According to example embodiments, a memory module includes a module substrate having a first surface and a second surface opposite to the first surface, the module substrate extending in a first direction; a plurality of electronic devices mounted on the first surface of the module substrate; a heat sink thermally coupled with the first surface of the module substrate, the heat sink including a base plate on the plurality of electronic devices and a plurality of central heat dissipating fins on a central region of an upper surface of the base plate, the base plate including first and second side portions extending in a second direction perpendicular the first direction and third and fourth side portions extending in the first direction, and the heat sink extending between the third side portion and the fourth side portion; and a plurality of adsorption work-pads respectively on end portions of the plurality of central heat dissipating fins, each of the plurality of adsorption work-pads having a hinge portion fastened to an upper surface of central heat dissipating fin and a folding portion extending from the hinge portion in the first direction and foldable by a certain angle relative to the first direction centered on the hinge portion.

According to example embodiments, a memory module includes a module substrate having a first surface and a second surface opposite to the first surface, the module substrate extending in a first direction; a plurality of electronic devices mounted on the first surface of the module substrate via a plurality of connection members; a base plate coupled with the first surface of the module substrate and on the plurality of electronic devices, the base plate having first and second side portions extending in a second direction perpendicular the first direction and third and fourth side portions extending in the first direction; a plurality of central heat dissipating fins on a central region of an upper surface of the base plate and extending between the third side portion and the fourth side portion; an intermediate member configured to transfer heat and between the base plate and the plurality of electronic devices; and a plurality of adsorption work-pads alternatively on end portions of the plurality of central heat dissipating fins, each of the adsorption work-pads having a hinge portion bonded to an upper surface of central heat dissipating fin and extending in the second direction, and a folding portion extending from the hinge portion along the first direction and foldable by a certain angle relative to the first direction centered on the hinge portion.

According to example embodiments, a memory module may include a module substrate having a first surface and a second surface opposite to the first surface, a plurality of electronic devices mounted on the first surface of the module substrate, a heat sink providing a base plate disposed on the plurality of electronic devices and a plurality of heat dissipating fins on an upper surface of the base plate to be spaced apart from each other, and a plurality of adsorption work-pads wherein each of the adsorption work-pads is provided on an end portion of the heat dissipating fin.

Each of the adsorption work-pads may include a hinge portion bonded to an upper surface of the heat dissipating fin and a folding portion extending from the hinge portion along the first direction and foldable by a certain angle relative to the hinge portion. Additionally, the adsorption work-pads may have a first angle relative to the heat dissipating fin. Further, the adsorption work-pad may be disposed on the end portion of the heat dissipating fin such that the adsorption work-pad are foldable along a circumferential direction to have a second angle greater than the first angle relative to the heat dissipating fin.

Accordingly, an automated assembly processing may be possible by using vacuum pick-up apparatus because a nozzle is attached to an upper surface of the adsorption work pad. Furthermore, the adsorption work-pads may expose an upper surface of the heat sink to more effectively dissipate heat inside the memory module to the outside.

### BRIEF DESCRIPTION OF THE DRAWINGS

FIG. 1 is a cross-sectional view illustrating a memory module in accordance with example embodiments.

FIG. 2 is an enlarged view illustrating portion ‘M1’ in FIG. 1.

FIG. 3 is a perspective view illustrating the memory module in FIG. 1.

FIG. 4 is a plan view illustrating the memory module in FIG. 1.

FIG. 5 is a cross-sectional view illustrating the memory module in FIG. 1, wherein the memory module is adsorbed by a vacuum pick-up apparatus.

FIG. 6 is an enlarged view illustrating portion ‘M2’ in FIG. 5.

FIG. 7 is a plan view illustrating the memory module in FIG. 5.

FIGS. 8 to 18 are views illustrating a method of manufacturing a memory module in accordance with example embodiments.

FIG. 19 is a cross-sectional view illustrating a memory module in accordance with example embodiments.

FIG. 20 is an enlarged view illustrating portion ‘M5’ in FIG. 19.

FIG. 21 is a cross-sectional view illustrating a memory module in accordance with example embodiments.

### DETAILED DESCRIPTION OF EXAMPLE EMBODIMENTS

Hereinafter, example embodiments will be explained in detail with reference to the accompanying drawings.

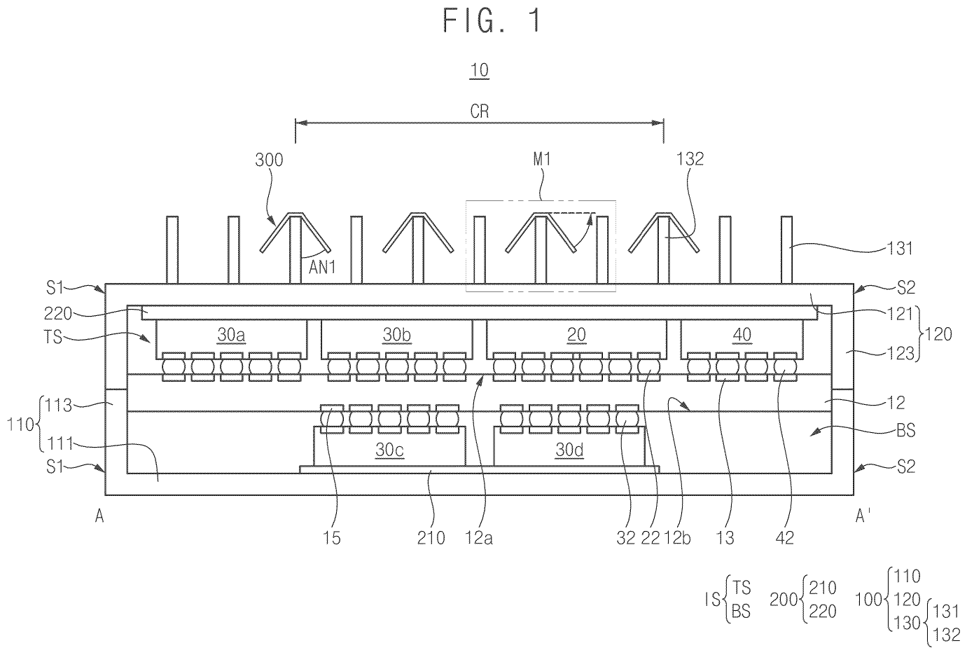

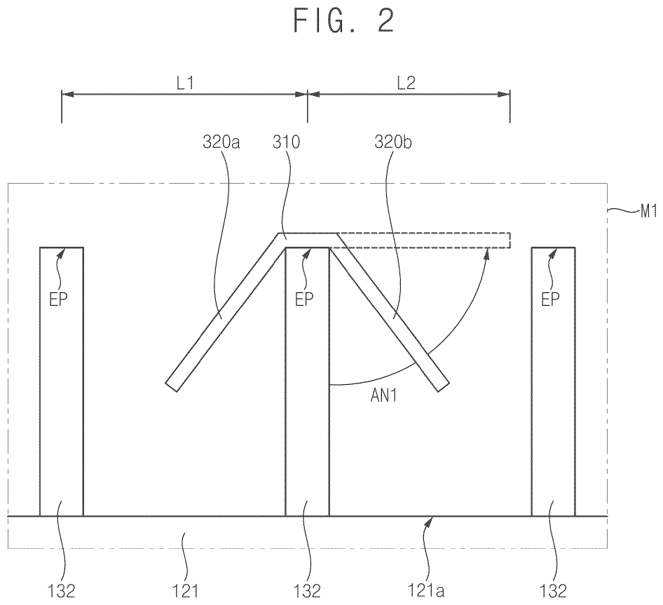

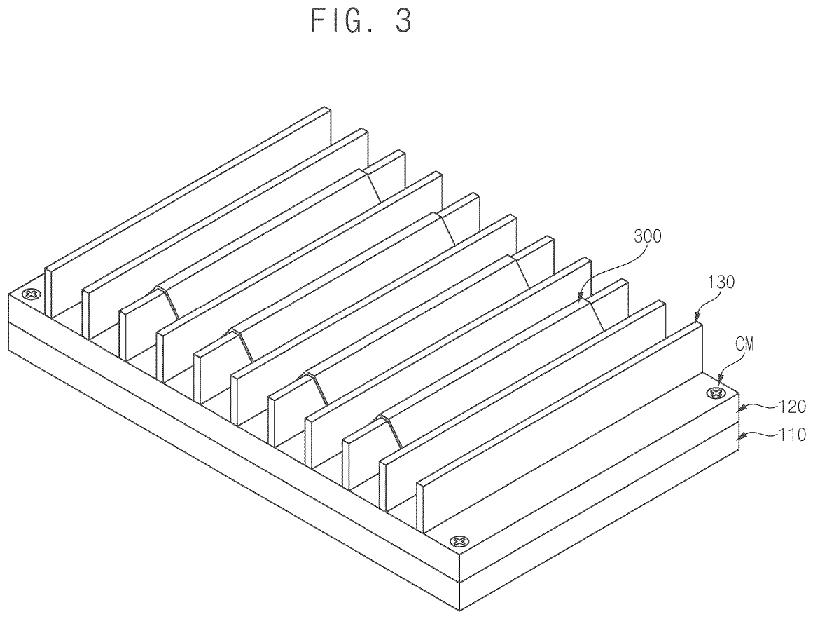

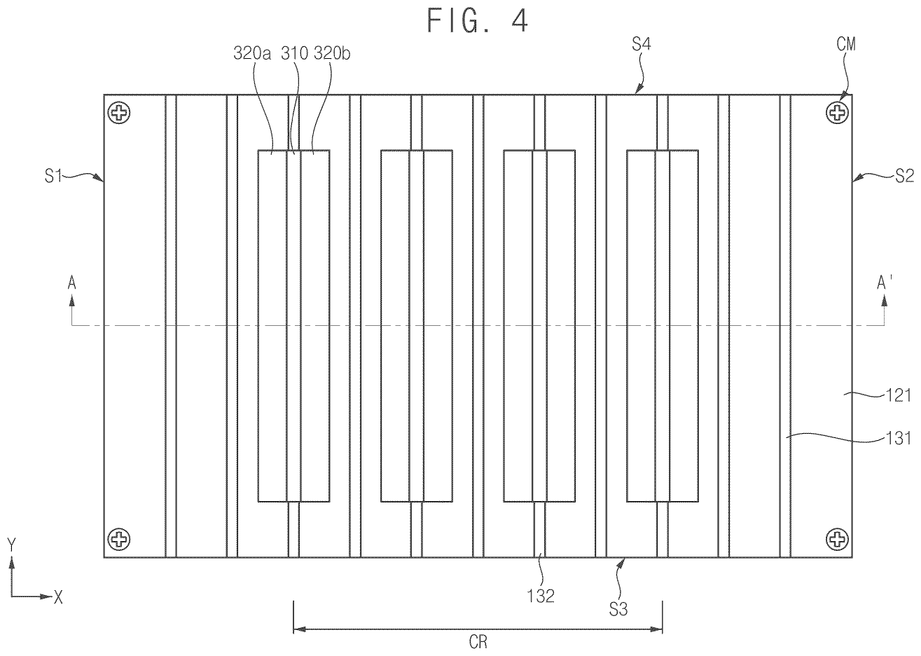

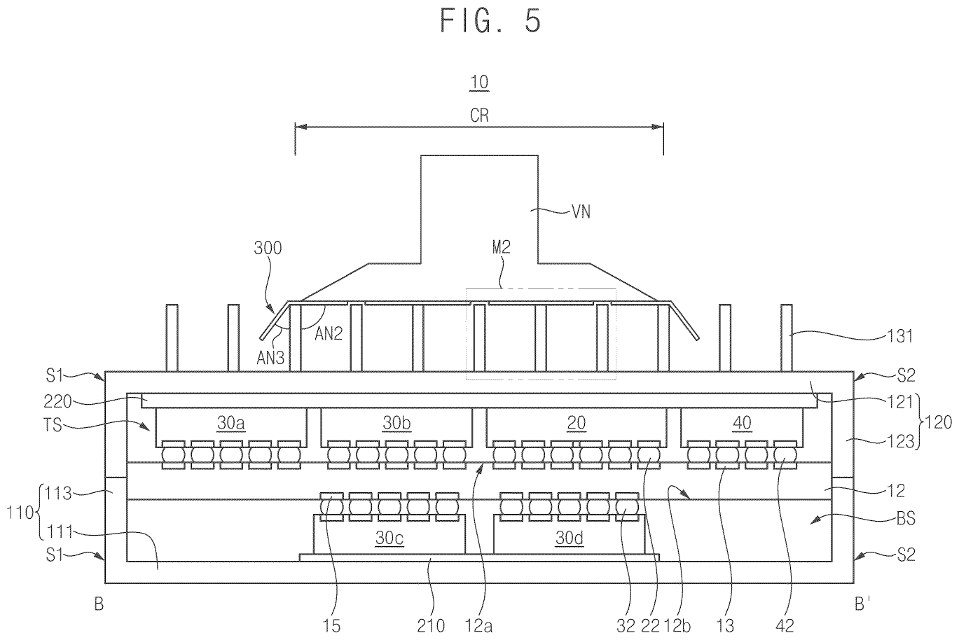

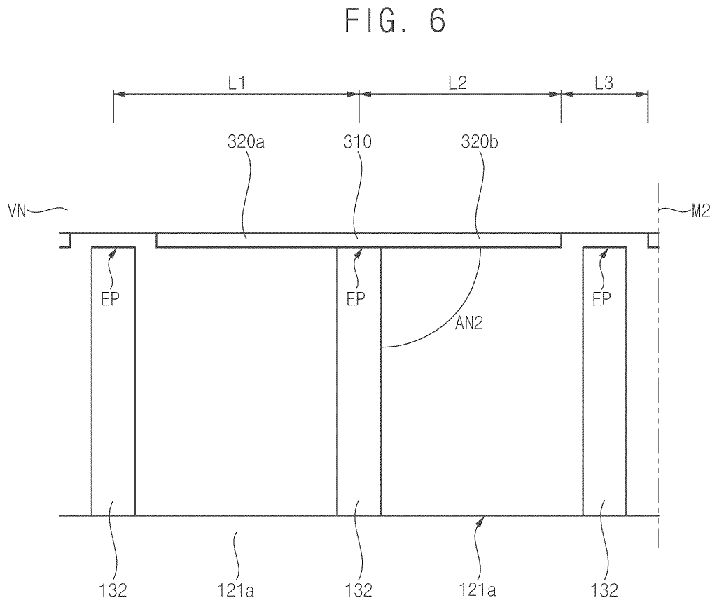

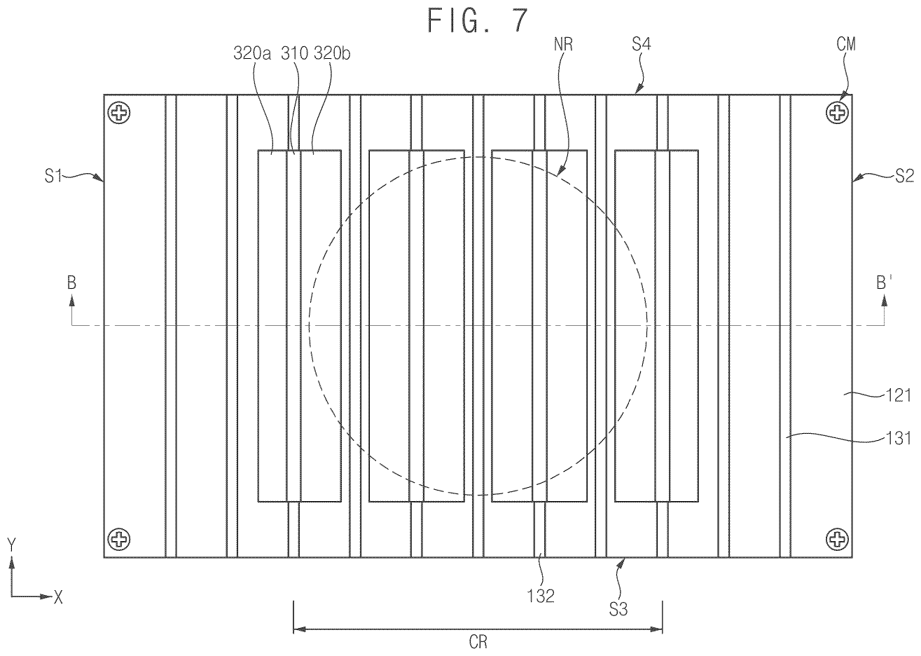

FIG. 1 is a cross-sectional view illustrating a memory module in accordance with example embodiments. FIG. 2 is an enlarged view illustrating portion ‘M1’ in FIG. 1. FIG. 3 is a perspective view illustrating the memory module in FIG. 1. FIG. 4 is a plan view illustrating the memory module in FIG. 1. FIG. 1 is a cross-sectional view taken along the line A-A′ in FIG. 4. FIG. 5 is a cross-sectional view illustrating the memory module in FIG. 1, wherein the memory module is adsorbed by a vacuum pick-up apparatus. FIG. 6 is an enlarged view illustrating portion ‘M2’ in FIG. 5. FIG. 7 is a plan view illustrating the memory module in FIG. 5. FIG. 5 is a cross-sectional view taken along the line B-B′ in FIG. 7.

Referring to FIGS. 1 to 7, a memory module 10 may include a module substrate 12, a plurality of upper electronic devices 20, 30a, 30b, and 40 mounted on the module substrate 12, a plurality of lower electronic devices 30c and 30d mounted on the module substrate 12, a heat sink 100 having a heat-sink body 110 and 120 that surrounds the plurality of upper electronic devices 20, 30a, 30b, and 40 and the plurality of lower electronic devices 30c, 30D to dissipate heat and a plurality of heat dissipating fins 130 that are disposed on an upper surface of the heat-sink body to be spaced apart from each other, and a plurality of adsorption work-pads 300 disposed respectively on end portions of the plurality of heat dissipating fins 130. Additionally, the memory module 10 may further include an intermediate member 200 respectively disposed between the heat-sink body 110 and 120 and the plurality of upper electronic devices 20, 30a, 30b, 40 and between the heat-sink body 110 and 120 and the plurality of lower electronic devices 30c, 30d. Additionally, the memory module 10 may further include a plurality of conductive connection members 22, 32, and 42 respectively disposed between the module substrate 12 and the plurality of upper electronic devices 20, 30a, 30b, 40 and between the module substrate 12 and the plurality of lower electronic devices 30c and 30d.

For example, the memory module 10 may be an electronic device, such as a solid-state drive (SSD) as a storage device. For example, the memory module may include a plurality of semiconductor devices such as NAND, DRAM, controller, etc.

In example embodiments, the module substrate 12 may extend in a first direction (X-direction) and may have an upper surface 12a and a lower surface 12b opposite to the upper surface 12a. Additionally, the module substrate 12 may include a plurality of upper pads 13 that are exposed from the upper surface 12a and a plurality of lower pads 15 that are exposed from the lower surface 12b. For example, the plurality of upper pads may be arranged on the upper surface 12a as an array form. The plurality of lower pads may be arranged on the lower surface 12b as an array form.

In example embodiments, the plurality of upper electronic devices may include a first electronic device 20, a plurality of second electronic devices 30a and 30b, collectively 30, and a third electronic device 40. The plurality of upper electronic devices may be mounted on the upper surface 12a of the module substrate 12. For example, the plurality of upper electronic devices may be mounted on the upper surface 12a of the module substrate 12 via a plurality of conductive connection members that are provided between the module substrate 12 and the plurality of upper electronic devices.

For example, the first electronic device 20 may be mounted on the upper surface 12a of the module substrate 12 via a plurality of first connection members 22 that are provided between the module substrate 12 and the first electronic device 20. For example, the first electronic device may include a logic chip including logic circuitry. The logic chip may be a controller configured to control memory elements. The first electronic device may include a processor chip such as an application processor (AP) and an ASIC as a host, such as a CPU, GPU, SOC, etc.

For example, the plurality of second electronic devices 30 may include first to fourth semiconductor devices 30a, 30b, 30c, and 30d. The first semiconductor device 30a and the second semiconductor device 30b may be mounted on the upper surface 12a of the module substrate 12 via a plurality of second connection members 32. For example, the first semiconductor device 30a and the second semiconductor device 30b may include non-volatile memory devices such as flash memory devices, PRAM devices, MRAM devices, RRAM devices, and the like.

For example, the third electronic device 40 may be mounted on the upper surface 12a of the module substrate 12 via a plurality of third connection members 42 that are provided between the module substrate 12 and the third electronic device 40. For example, the third electronic device may include a volatile memory device such as an SRAM device, a DRAM device, or the like.

In example embodiments, the plurality of lower electronic devices may include the third semiconductor device 30c and the fourth semiconductor device 30d of the plurality of second electronic devices 30. The plurality of lower electronic devices may be mounted on the lower surface 12b of the module substrate 12. For example, the plurality of lower electronic devices may be mounted on the module substrate 12 via a plurality of conductive connection members that are provided between the module substrate 12 and the plurality of lower electronic devices.

For example, the plurality of lower electronic devices may include the third semiconductor device 30c and the fourth semiconductor device 30d of the plurality of second electronic devices 30. For example, the third semiconductor device 30c and the fourth semiconductor device 30d may be mounted on the lower surface 12b of the module substrate 12 via the plurality of second connection members 32. For example, the third semiconductor device 30c and the fourth semiconductor device 30d may include non-volatile memory devices such as flash memory devices, PRAM devices, MRAM devices, RRAM devices, and the like.

In example embodiments, the heat sink 100 may include the heat-sink body including a lower heat-sink 110 and an upper heat-sink 120 that are configured to dissipate heat and the plurality of heat dissipating fins 130 provided on the heat-sink body. Additionally, the heat sink 100 may further include a plurality of connectors CM that are configured to integrally connect the lower heat-sink 110 and the upper heat-sink 120. For example, the heat sink may be a metallic structure for more effectively dissipating heat generated by the memory module to the outside. For example, the heat sink may include aluminum (Al) or an alloy thereof.

In example embodiments, the lower heat-sink 110 may include a lower base plate 111 that extends in the first direction (X direction) and is provided under the plurality of lower electronic devices, and a plurality of side walls 113 that extend from the lower base plate 111 toward the module substrate 12. For example, the lower base plate 111 may include first and second side portions S1, S2 extending in the second direction (Y direction) and third and fourth side portions S3, S4 extending in the first direction (X direction). For example, the plurality of first side walls 113 may be structures that extend from the first to fourth side portions S1, S2, S3, and S4 of the lower base plate 111 to the lower surface 12b of the module substrate 12.

The lower heat-sink may be disposed on the lower surface of the module substrate 12 to surround the plurality of lower electronic devices. For example, the third semiconductor device 30c and the fourth semiconductor device 30d may be disposed within a lower space BS that is defined by the lower surface 12b of the module substrate 12 and the lower base plate 111 and the plurality of first side walls 113 of the lower heat-sink 110.

In example embodiments, the upper heat-sink 120 may include an upper base plate 121 that extends in the first direction (X direction) and is provided on upper surfaces of the plurality of upper electronic devices, and a plurality of second side walls 123 that extend from the upper base plate 121 towards the module substrate 12. For example, the upper base plate 121 may include first and second side portions S1, S2 extending in the second direction (Y direction) and third and fourth side portions S3, S4 extending in the first direction (X direction). For example, the plurality of second side walls 123 may be structures that extend from the first to fourth side portions S1, S2, S3, and S4 of the upper base plate 121 to the upper surface 12a of the module substrate 12. That is the upper and lower heat-sinks 110 and 120 may cooperatively close around the interior. However, example embodiments are not limited thereto, and for example, there may be openings, etc.

The upper heat-sink may be disposed on the upper surface of the module substrate 12 to surround the plurality of upper electronic devices. For example, the first electronic device 20, the first semiconductor device 30a, the second semiconductor device 30b, and the third electronic device 40 may be disposed within an upper space TS that is defined by the upper surface 12a of the module substrate 12 and the upper base plate 121, and the plurality of second side walls 123 of the upper heat-sink 120.

For example, the lower heat-sink 110 and the upper heat-sink 120 may define an internal space IS including the upper space TS and the lower space BS. The internal space IS may be defined by the plurality of first side walls 113 of the lower heat-sink 110 and the plurality of second side walls 123 of the upper heat-sink 120 corresponding to each other. For example, the module substrate, the plurality of upper electronic devices mounted on the module substrate, and the plurality of lower electronic devices mounted on the module substrate may be disposed within the internal space.

In example embodiments, the plurality of heat dissipating fins 130 may include a plurality of central heat dissipating fins 132 provided in a central region CR of the upper heat-sink 120 and a plurality of peripheral heat dissipating fins 131 provided in a peripheral region surrounding the central region CR. For example, the plurality of heat dissipating fins may be structures configured to more effectively dissipate heat transferred from the upper surface of the upper heat-sink. For example, the plurality of heat dissipating fins may be structures configured to increase a heat dissipation area to more effectively dissipate internal heat generated by semiconductor devices such as NAND, DRAM, controller, etc. which are provided inside the memory module.

The plurality of heat dissipating fins 130 may be disposed on an upper surface of the upper heat-sink to extend between side portions of the upper heat-sink 120. For example, the first side portion S1 and the second side portion S2 of the upper base plate 121 may face each other and extend in the second direction (Y direction) perpendicular to the first direction (X direction). The third side portion S3 and the fourth side portion S4 of the upper base plate 121 may face each other and extend in the first direction (X direction). For example, each of the plurality of heat dissipating fins 130 may extend between the third side portion S3 and the fourth side portion S4 and the plurality of heat dissipating fins 130 may be arranged to be spaced apart from each other in the first direction (X direction).

The plurality of heat dissipating fins 130 may include a plurality of protrusions that protrude from an upper surface 121a of the upper base plate 121 of the upper heat-sink 120. For example, the plurality of heat dissipating fins 130 may include the plurality of protrusions that extend upwardly to have a predetermined (or, alternatively, desired or selected) height from the upper surface 121a of the upper base plate 121.

In example embodiments, the plurality of connectors CM may be respectively disposed at corners of the lower base plate 111 and the upper base plate 121 and may penetrate the lower base plate 111 and the upper base plate 121. For example, the plurality of connectors may include a plurality of fastening screws configured to integrally couple the lower base plate 111 and the upper base plate 121.

In example embodiments, the intermediate member 200 may include a first intermediate member 210 that is disposed between the lower base plate 111 and the plurality of lower electronic devices 30c and 30d and a second intermediate member 220 that is disposed between the upper base plate 121 and the plurality of upper electronic devices 20, 30a, 30b and 40. For example, the intermediate member 200 may be a structure that is configured to more effectively transfer heat inside the memory module to the heat sink 100. For example, the intermediate member 200 may include a flexible thermal interface material (flexible TIM). For example, the intermediate member may include a polymer resin, aluminum oxide (Al₂O₃), silicon carbide (SiC), etc.

For example, the first intermediate member 210 may fill or substantially fill a gap provided between the lower base plate 111 and the plurality of lower electronic devices 30c, 30d to more effectively transfer heat generated by the plurality of lower electronic devices 30c and 30d to the lower heat-sink 110. The second intermediate member 220 may fill or substantially fill a gap provided between the upper base plate 121 and the plurality of upper electronic devices 20, 30a, 30b, 40 to more effectively transfer heat generated by the plurality of upper electronic devices 20, 30a, 30b and 40 to the upper heat-sink 120.

In example embodiments, each of the plurality of adsorption work-pads 300 may include a hinge portion 310 that is disposed on each of the plurality of central heat dissipating fins 132 provided in the central region CR of the upper base plate 121 and is bonded (or secured) to an upper surface of each of the plurality of central heat dissipating fins 132 and a folding portion 320 that extends from the hinge portion 310 in the first direction (X direction) and is foldable by a certain angle relative to the first direction (X direction) about (or at) the hinge portion 310.

For example, the plurality of adsorption work-pads may be structures configured to provide a contact surface to which a vacuum nozzle of a vacuum pick-up apparatus is attached when the memory module is picked up and moved by using the vacuum pick-up apparatus. The plurality of adsorption work-pads may be structures configured to expose a portion of the upper surface of the heat sink 100 to more effectively dissipate heat generated within the memory module.

For example, the hinge portion and the folding portion may serve as a pad when it comes into contact with the vacuum nozzle of the vacuum pick-up apparatus. For example, a portion of the hinge portion in contact with the vacuum nozzle may serve as a hinge pad. Additionally, a portion of the folding portion in contact with the vacuum nozzle may serve as a folding pad.

For example, the plurality of adsorption work-pads 300 may include a flexible thermal interface material (flexible TIM). The plurality of adsorption work-pads may include a polymer resin, aluminum oxide (Al₂O₃), silicon carbide (SiC), etc.

The plurality of adsorption work-pads 300 may be disposed on end portions of the plurality of central heat dissipating fins 132 to extend in the second direction (Y direction) respectively. For example, the plurality of adsorption work-pads 300 may be alternately disposed on portions of the plurality of central heat dissipating fins 132. Each of the plurality of adsorption work-pads 300 may have first and second foldable pads 320a, 320b that extend in opposite directions from the end portion of each of the plurality of central heat dissipating fins 132 toward the upper surface 121a of the upper base plate 121. The first and second foldable pads 320a, 320b may respectively extend in the second direction (Y direction).

A pair of the first foldable pad 320a and the second foldable pad 320b may be disposed on the end portion each of the plurality of central heat dissipating fins 132 to be fordable along a circumferential direction with respect to the end portion. For example, each of the first and second foldable pads 320a and 320b may be folded to have a first angle AN1 with respect to a vertical extension direction of the central heat dissipating fin. The first and second foldable pads 320a, 320b may be unfolded along the circumferential direction about (or at) the end portion of the central heat dissipating fin to have a second angle AN2 greater than the first angle AN1 with respect to the vertical extension direction of the central heat dissipating fin.

For example, in case that no external force is applied to the first and second foldable pads 320a and 320b, the first angle AN1 of the first and second foldable pads 320a and 320b in a folded state may have an acute angle. For example, the first angle AN1 may be about or exactly 45 degrees. Thus, the first and second foldable pads 320a and 320b may sufficiently expose the upper surface 121a of the upper base plate 121 of the upper heat-sink 120 to efficiently allow airflow in contact with the upper surface 121a, to thereby more effectively dissipate heat generated inside the memory module.

In addition, in case that the external force is applied to the first and second foldable pads 320a and 320b, the first and second foldable pads 320a, 320b may be unfolded to have the second angle AN2 that is greater than the first angle AN1. For example, the second angle AN2 of the first and second foldable pads 320a and 320b in an unfolded state may be about or exactly 90 degrees. For example, after positioning the vacuum nozzle VN of the vacuum pick-up apparatus on the first and second foldable pads 320a and 320b, vacuum pressure may be applied to the vacuum nozzle VN to unfold the first and second foldable pads 320a and 320b such that first and second foldable pads 320a and 320b are adsorbed to a suction surface of the vacuum nozzle VN of the vacuum pick-up apparatus. Accordingly, the first and second foldable pads 320a, 320b may provide a region NR to be in contact with the vacuum nozzle VN, so that the vacuum pick-up apparatus picks up and transfer the memory module. As such, a gap between adjacent foldable pads 320a, 320b has a third length L3. And, the third length is wholly or partially overlapping portion of the central heat dissipating fins 131.

A length of each of the first and second foldable pads may be less than a spacing distance between the adjacent heat dissipating fins 130. For example, the spacing distance between the adjacent heat dissipating fins 130 may have a first length L1. The length of each of the first and second foldable pads 320a, 320b may have a second length L2. For example, the first length L1 may be greater than the second length L2.

As mentioned above, the memory module 10 may include the module substrate 12 having the upper surface 12a and the lower surface 12b opposite to each other, the plurality of upper electronic devices mounted on the upper surface 12a of the module substrate 12, the plurality of lower electronic devices mounted on the lower surface 12b of the module substrate 12, the heat sink 100 including the heat-sink body 110 and 120 and the plurality of heat dissipating fins 130 disposed on the upper surface of the heat-sink body 110 and 120 to be spaced apart from each other, and the plurality of adsorption work-pads 300 disposed on the end portions of the plurality of heat dissipating fins 130.

Each of the adsorption work-pads 300 may include the hinge portion 310 that is bonded to an upper surface of each of the plurality of central heat dissipating fins 132 disposed in the central region CR of the upper base plate 121 and the folding portion 320 that extends from the hinge portion 310 in the first direction (X direction) and is foldable by a certain angle relative to the hinge portion 310. Additionally, the folding portion 320 may include the first foldable pads 320a and the second foldable pads 320b each having the first angle AN1 with respect to the extending direction of the central heat dissipating fin. Further, the first foldable pads 320a and the second foldable pads 320b may be folded along the circumferential direction with respect to the end portion of the central heat dissipating fin to have the second angle AN2 that is greater than the first angle AN1.

Accordingly, an automated assembly process may be possible by using the vacuum pick-up apparatus because the nozzle vacuum suctions the upper surfaces of the adsorption work-pads 300. Further the adsorption work-pads 300 may expose the upper surface of the upper base plate to more effectively dissipate heat inside the memory module to the outside.

Hereinafter, a method of manufacturing a memory module in accordance with example embodiments will be described.

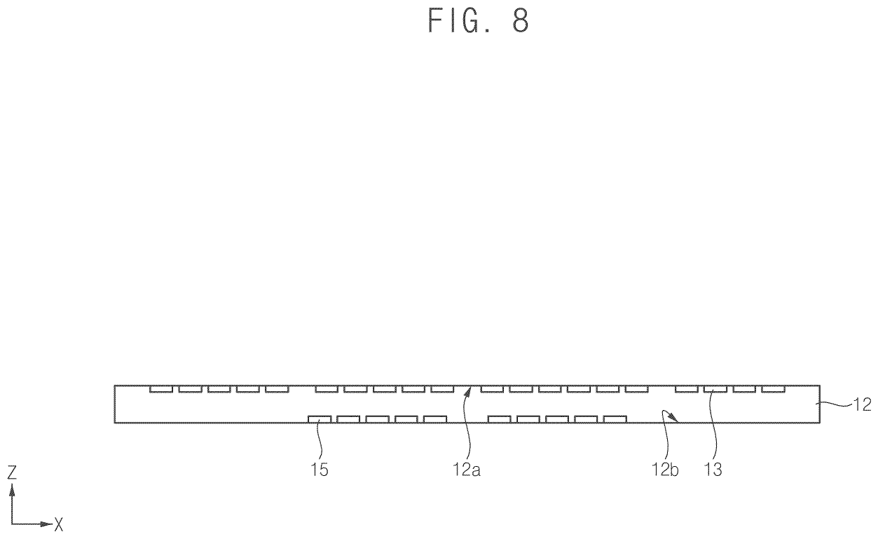

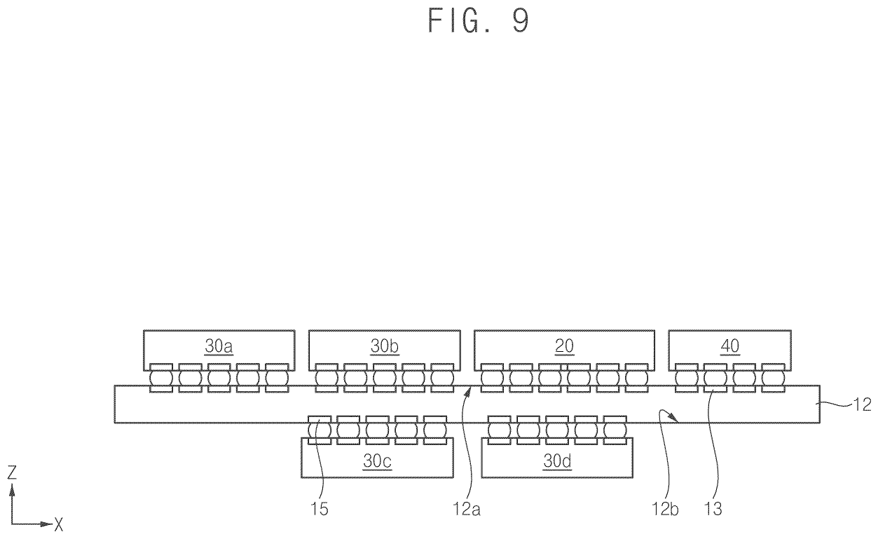

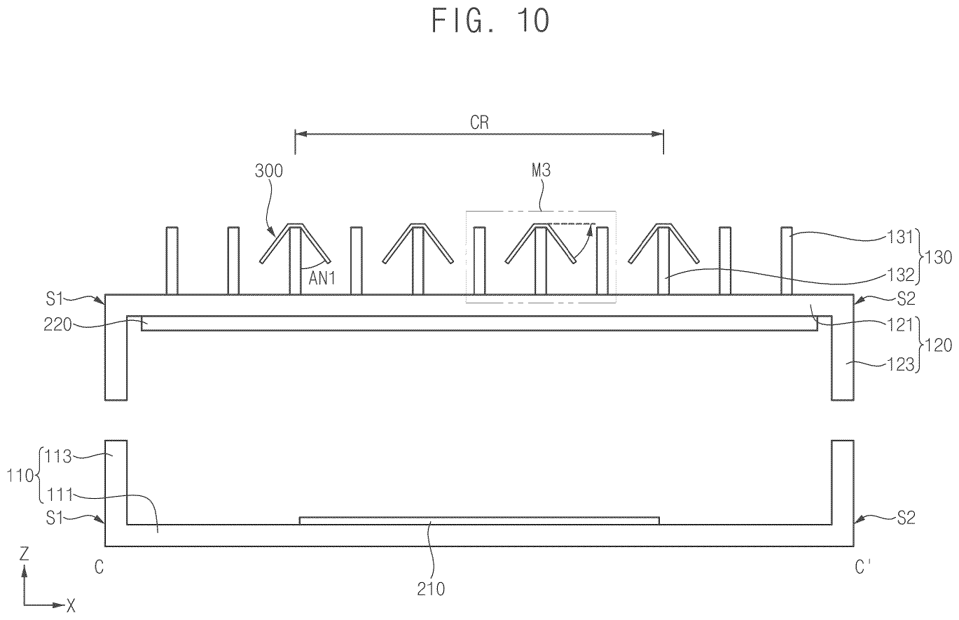

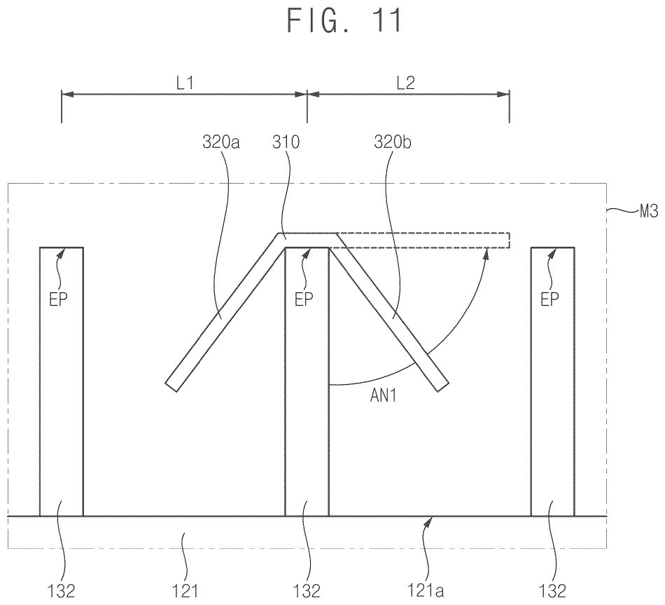

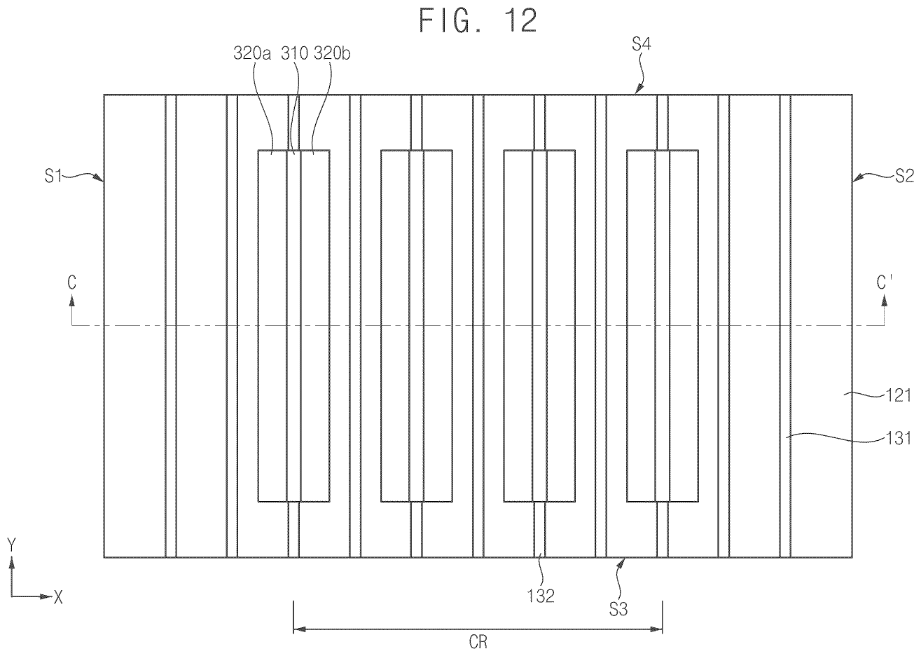

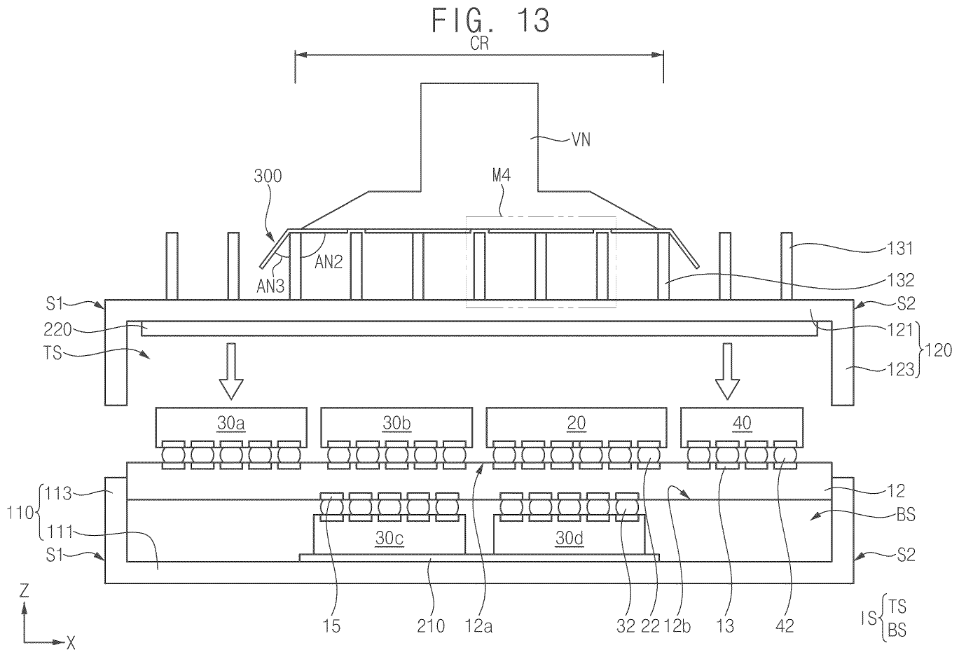

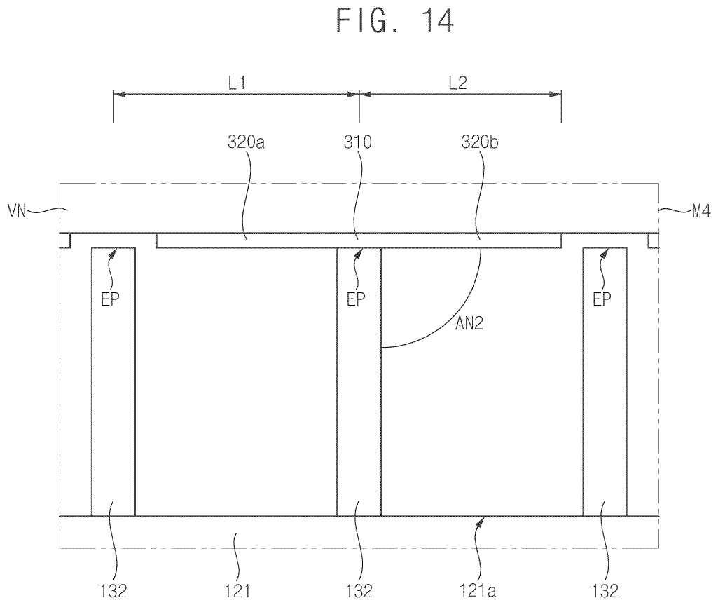

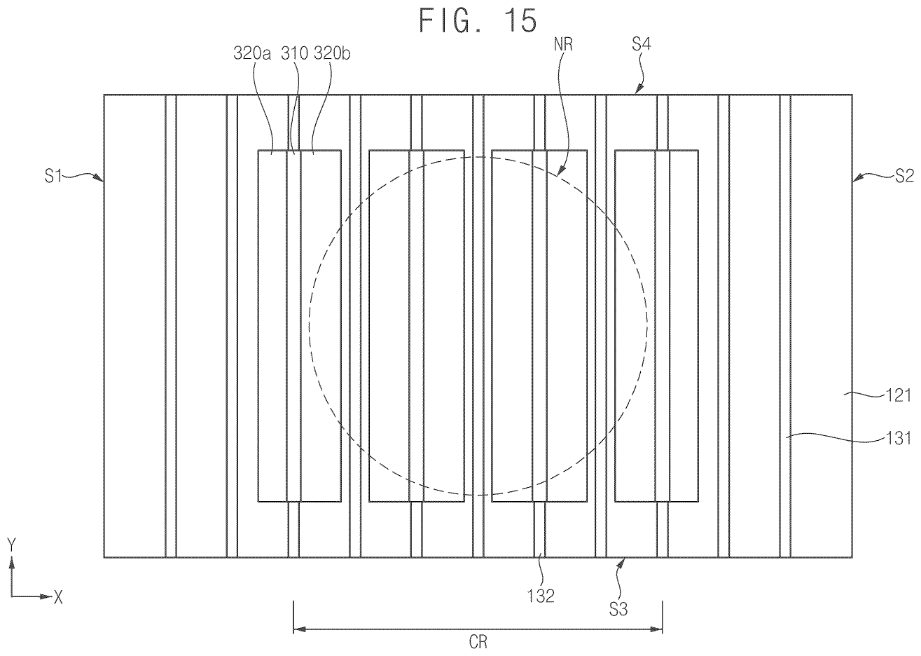

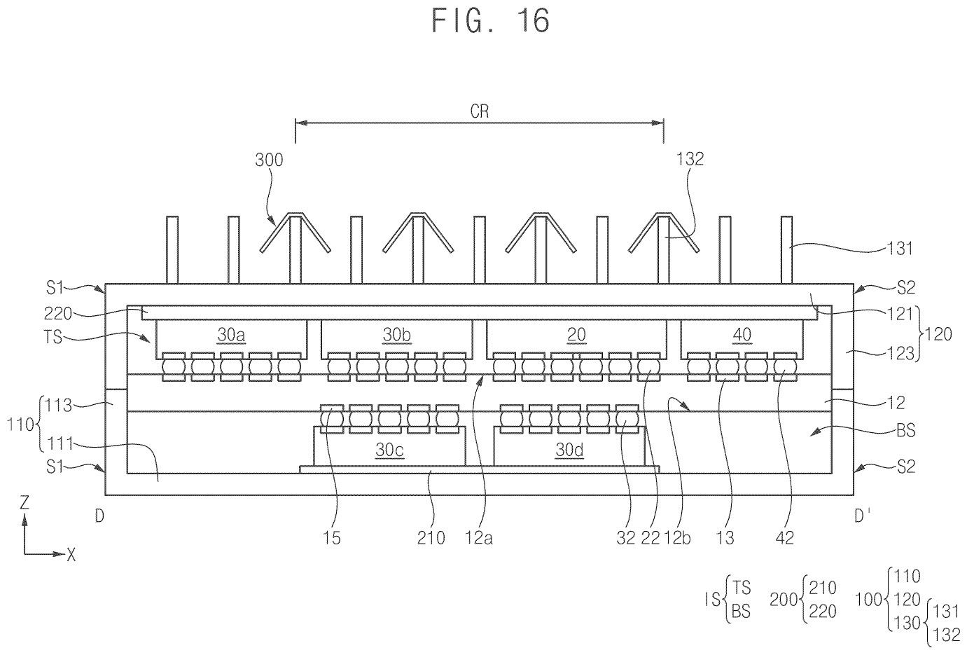

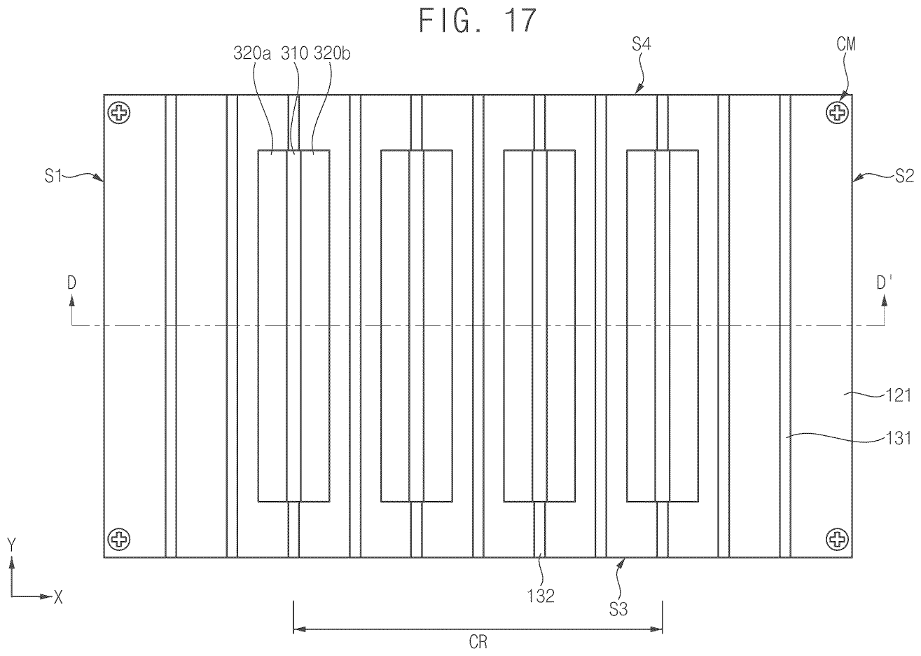

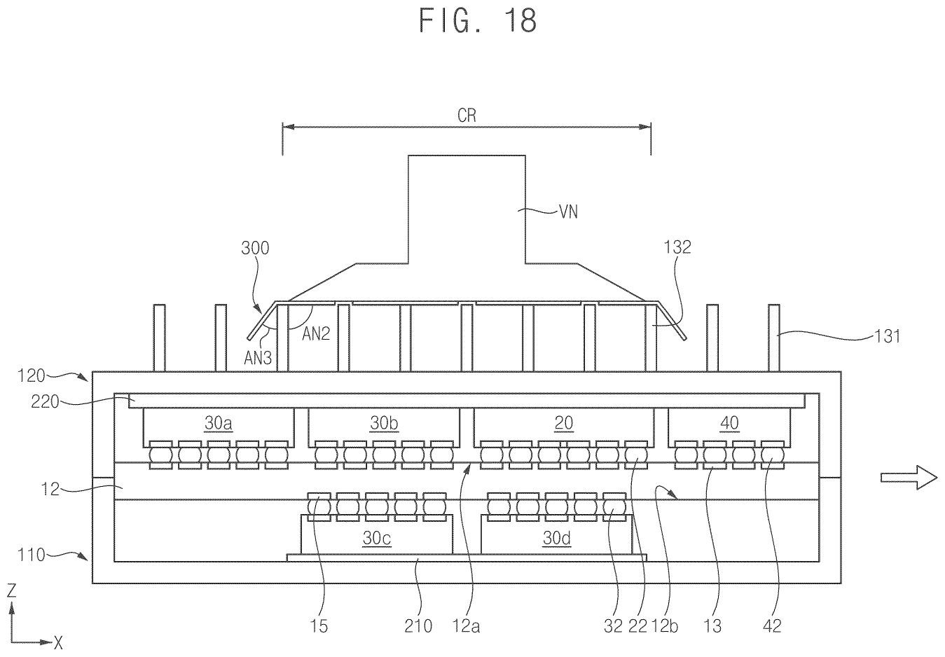

FIG. 8 is a cross-sectional view illustrating a memory substrate in accordance with example embodiments. FIG. 9 is a cross-sectional view illustrating a plurality of electronic devices mounted on the memory substrate of FIG. 8. FIG. 10 is a cross-sectional view illustrating a heat sink in accordance with example embodiments. FIG. 11 is an enlarged view illustrating portion ‘M3’ in FIG. 10. FIG. 12 is a plan view illustrating the heat sink in FIG. 10. FIG. 10 is a cross-sectional view taken along the line C-C′ in FIG. 12. FIG. 13 is a cross-sectional view illustrating the heat sink in FIG. 10, wherein the heat sink is picked up and moved by a vacuum pick-up apparatus. FIG. 14 is an enlarged view illustrating portion ‘M4’ in FIG. 13. FIG. 15 is a plan view illustrating an upper surface of the heat sink adsorbed by the vacuum pick-up apparatus. FIG. 16 is a cross-sectional view illustrating a memory module in accordance with example embodiments. FIG. 17 is a plan view illustrating a memory module in accordance with example embodiments. FIG. 16 is a cross-sectional view taken along the line D-D′ in FIG. 17. FIG. 18 is a cross-sectional view illustrating the memory module in FIG. 16, wherein the memory module is moved by a vacuum pick-up apparatus.

Referring to FIG. 8, a module substrate 12 may be provided for a memory module.

In example embodiments, the module substrate 12 may extend in a first direction (X-direction) and have an upper surface 12a and a lower surface 12b opposite to the upper surface 12a. The module substrate 12 may include a plurality of upper pads 13 exposed from the upper surface 12a and a plurality of lower pads 15 exposed from the lower surface 12b. For example, the plurality of upper pads may be arranged on the upper surface 12a as an array form. The plurality of lower pads may be arranged on the lower surface 12b as an array form.

Referring to FIG. 9, a plurality of upper electronic devices may be mounted on the upper surface 12a of the module substrate 12, and a plurality of lower electronic devices may be mounted on the lower surface 12b of the module substrate 12.

In example embodiments, the plurality of upper electronic devices may include a first electronic device 20, a first semiconductor device 30a and a second semiconductor device 30b of a plurality of second electronic devices 30, and a third electronic device 40. The plurality of upper electronic devices may be mounted on the upper surface 12a of the module substrate 12. For example, the plurality of upper electronic devices may be mounted on the upper surface 12a of the module substrate 12 via a plurality of conductive connection members that are provided between the module substrate 12 and the plurality of upper electronic devices.

For example, the first electronic device 20 may be mounted on the upper surface 12a of the module substrate 12 via a plurality of first connection members 22 that are provided between the module substrate 12 and the first electronic device 20. For example, the first electronic device may include a logic chip including logic circuitry. The logic chip may be a controller configured to control memory elements. The first electronic device may include a processor chip such as an application processor (AP) and an ASIC as a host, such as a CPU, GPU, SOC, etc.

For example, the plurality of second electronic devices 30 may include first to fourth semiconductor devices 30a, 30b, 30c, and 30d. The first semiconductor device 30a and the second semiconductor device 30b may be mounted on the upper surface 12a of the module substrate 12 via a plurality of second connection members 32. For example, the first semiconductor device 30a and the second semiconductor device 30b may include non-volatile memory devices such as flash memory devices, PRAM devices, MRAM devices, RRAM devices, and the like.

For example, the third electronic device 40 may be mounted on the upper surface 12a of the module substrate 12 via a plurality of third connection members 42 provided between the module substrate 12 and the third electronic device 40. For example, the third electronic device may include a volatile memory device such as an SRAM device, a DRAM device, or the like.

In example embodiments, the plurality of lower electronic devices may include a third semiconductor device 30c and a fourth semiconductor device 30d of the plurality of second electronic devices 30. The plurality of lower electronic devices may be mounted on the lower surface 12b of the module substrate 12. For example, the plurality of lower electronic devices may be mounted on the module substrate 12 via a plurality of conductive connection members provided between the module substrate 12 and the plurality of lower electronic devices.

For example, the plurality of lower electronic devices may include the third semiconductor device 30c and the fourth semiconductor device 30d of the plurality of second electronic devices 30. For example, the third semiconductor device 30c and the fourth semiconductor device 30d may be mounted on the lower surface 12b of the module substrate 12 via the plurality of second connection members 32. For example, the third semiconductor device 30c and the fourth semiconductor device 30d may include non-volatile memory devices such as flash memory devices, PRAM devices, MRAM devices, RRAM devices, and the like.

Referring to FIGS. 10 to 12, a heat sink 100 for more effectively dissipating heat inside the memory module to the outside, an intermediate member 200 disposed on inner surface of the heat sink 100, and a plurality of adsorption work-pads 300 disposed on an upper surface of the heat sink 100 may be provided.

In example embodiments, the heat sink 100 may include a heat-sink body including a lower heat-sink 110 and an upper heat-sink 120 that are configured to dissipate heat and a plurality of heat dissipating fins 130 that are provided on the heat-sink body. The heat-sink 100 may include a plurality of connectors CM (not shown) that are configured to integrally connect the lower heat-sink 110 and the upper heat-sink 120. For example, the heat sink may be a metallic structure for more effectively dissipating heat generated by the memory module to the outside. For example, the heat sink may include aluminum (Al).

In example embodiments, the lower heat-sink 110 may include a lower base plate 111 that extends in the first direction (X direction) and is provided under the plurality of lower electronic devices, and a plurality of side walls 113 that extend from the lower base plate 111 toward the module substrate 12. For example, the lower base plate 111 may include first and second side portions S1, S2 extending in the second direction (Y direction) and third and fourth side portions S3, S4 extending in the first direction (X direction). For example, the plurality of first side walls 113 may be structures that extend from the first to fourth side portions S1, S2, S3, and S4 of the lower base plate 111 to the lower surface 12b of the module substrate 12.

In example embodiments, the upper heat-sink 120 may include an upper base plate 121 that extend in the first direction (X direction) and is provided on upper surfaces of the plurality of upper electronic devices, and a plurality of second side walls 123 that extend from the upper base plate 121 towards the module substrate 12. For example, the upper base plate 121 may include first and second side portions S1, S2 extending in the second direction (Y direction) and third and fourth side portions S3, S4 extending in the first direction (X direction). For example, the plurality of second side walls 123 may be structures that extend from the first to fourth side portions S1, S2, S3, and S4 of the upper base plate 121 to the upper surface 12a of the module substrate 12.

In example embodiments, the plurality of heat dissipating fins 130 may include a plurality of central heat dissipating fins 132 provided on a central region CR of the upper heat-sink 120 and a plurality of peripheral heat dissipating fins 131 provided on a peripheral region except for the central region CR. For example, the plurality of heat dissipating fins may be structures configured to more effectively dissipate heat transferred from the upper surface of the upper heat-sink. For example, the plurality of heat dissipating fins may be structures configured to increase a heat dissipation area to more effectively dissipate internal heat generated by semiconductor devices such as NAND, DRAM, controller, etc. which are provided inside the memory module.

The plurality of heat dissipating fins 130 may be disposed on the upper surface of the upper heat-sink to extend between side portions of the upper heat-sink 120. For example, the first side portion S1 and the second side portion S2 of the upper base plate 121 may face each other and extend in the second direction (Y direction) perpendicular to the first direction (X direction). The third side portion S3 and the fourth side portion S4 of the upper base plate 121 may face each other and extend in the first direction (X direction). For example, each of the plurality of heat dissipating fins 130 may extend between the third side portion S3 and the fourth side portion S4 and the plurality of heat dissipating fins 130 may be arranged to be spaced apart from each other in the first direction (X direction).

The plurality of heat dissipating fins 130 may include a plurality of protrusions that protrude from an upper surface 121a of the upper base plate 121 of the upper heat-sink 120. For example, the plurality of heat dissipating fins 130 may include the plurality of protrusions that extend upwardly to have a predetermined (or, alternatively, desired or selected) height from the upper surface 121a of the upper base plate 121.

In example embodiments, the intermediate member 200 may include a first intermediate member 210 that is disposed between the lower base plate 111 and the plurality of lower electronic devices 30c and 30d and a second intermediate member 220 that is disposed between the upper base plate 121 and the plurality of upper electronic devices 20, 30a, 30b and 40. For example, the intermediate member 200 may be a structure that is configured to more effectively transfer heat inside the memory module to the heat sink 100. For example, the intermediate member 200 may include a flexible thermal interface material (flexible TIM). For example, the intermediate member 200 may include a polymer resin, aluminum oxide (Al₂O₃), and silicon carbide (SIC).

In example embodiments, each of the plurality of adsorption work-pads 300 may include a hinge portion 310 that is disposed on each of the plurality of central heat dissipating fins 132 provided on the central region CR of the upper base plate 121 and is bonded (or secured) to an upper surface of each of the plurality of central heat dissipating fins 132 and a folding portion 320 that extends from the hinge portion 310 in the first direction (X direction) and is foldable by a certain angle with respect to the first direction (X direction) centered on the hinge portion 310.

For example, the plurality of adsorption work-pads may be structures configured to provide a contact surface to which a vacuum nozzle of a vacuum pick-up apparatus is attached when the memory module is adsorbed and moved by using the vacuum pick-up apparatus. The plurality of adsorption work-pads may be structures configured to expose a portion of the upper surface of the heat sink 100 to more effectively dissipate heat generated within the memory module.

For example, the hinge portion and the folding portion may have serve as a pad when it comes into contact with the vacuum nozzle of the vacuum pick-up apparatus. For example, a portion of the hinge portion in contact with the vacuum nozzle may serve as a hinge pad. Additionally, a portion of the folding portion in contact with the vacuum nozzle may serve as a folding pad.

For example, the plurality of adsorption work-pads 300 may include a flexible thermal interface material (flexible TIM). The plurality of adsorption work-pads may include a polymer resin, aluminum oxide (Al₂O₃), silicon carbide (SiC), etc.

The plurality of adsorption work-pads 300 may be disposed on end portions of the plurality of central heat dissipating fins 132 to extend in the second direction (Y direction).

For example, the plurality of adsorption work-pads 300 may be alternately disposed on portions of the plurality of central heat dissipating fins 132. Each of the plurality of adsorption work-pads 300 may have first and second foldable pads 320a and 320b that extend in opposite directions from the end portion of each of the plurality of central heat dissipating fins 132 toward the upper surface 121a of the upper base plate 121. The first and second foldable pads 320a and 320b may respectively extend in the second direction (Y direction).

For example, in case that no external force is applied to the first and second foldable pads 320a and 320b, the first angle AN1 of the first and second foldable pads 320a and 320b in a folded state may have an acute angle. For example, the first angle AN1 may be about or exactly 45 degrees. Thus, the first and second foldable pads 320a and 320b may sufficiently expose the upper surface 121a of the upper base plate 121 of the upper heat-sink 120 to efficiently allow airflow in contact with the upper surface 121a, to thereby more effectively dissipate heat generated inside the memory module.

A length of each of the first and second foldable pads may be less than a spacing distance between the adjacent heat dissipating fins 130. For example, the spacing distance between the adjacent heat dissipating fins 130 may have a first length L1. The length of each of the first and second foldable pads 320a, 320b may have a second length L2. For example, the first length L1 may be greater than the second length L2. The length of a gap between adjacent first and second foldable pads 320a, 320b may have a third length L3. For example, the third length L3 may be smaller than each of the first and second lengths L1, L2.

Referring to FIGS. 13 to 15, the module substrate 12 on which the plurality of upper electronic devices and the plurality of lower electronic devices are mounted may be disposed in the lower heat-sink 110. The vacuum nozzle VN of the vacuum pick-up apparatus may be moved over the plurality of adsorption work-pads 300, and then, the plurality of adsorption work-pads 300 may be unfolded to be adsorbed to a suction surface of the vacuum nozzle VN by using vacuum pressure. Then, the upper heat-sink 120 may be aligned over the lower heat-sink 110 by using the vacuum pick-up apparatus.

In particular, the module substrate 12 on which the plurality of upper electronic devices and the plurality of lower electronic devices are mounted may be positioned on the lower heat-sink 110 such that the plurality of lower electronic devices are disposed within a lower space BS that is defined by the plurality of first side walls 113 of the lower heat-sink 110 and the lower base plate 111. For example, the module substrate 12 may be disposed such that the lower surface 12b of the module substrate 12 faces the lower heat-sink 110.

The first intermediate member 210 of the intermediate member 200 may be provided to fill or substantially fill a gap between the lower heat-sink 110 and the plurality of lower electronic devices 30c and 30d, to more effectively transfer heat generated by the plurality of lower electronic devices 30c and 30d to the lower heat-sink 110.

Then, as the vacuum nozzle VN of the vacuum pick-up apparatus approaches the first and second foldable pads 320a and 320b, the first foldable pad 320a and the second foldable pad 320b may be bended at an angle with respect to a vertical extension direction of the central heat dissipating fin. For example, the first foldable pad 320a and the second foldable pad 320b may be unfolded along the circumferential direction about (or at) the end portion of each of the plurality of central heat dissipating fins 132 such that the first foldable pad 320a and the second foldable pad 320b have a second angle AN2 greater than the first angle AN1 with respect to the vertical extension direction of the central heat dissipating fin 132. For example, the second angle AN2 may be about or exactly 90 degrees.

Accordingly, the first foldable pad 320a and the second foldable pad 320b may provide a region NR to be in contact with the vacuum nozzle VN, so that the vacuum pick-up apparatus adsorbs and moves the memory module.

Then, the upper heat-sink 120 may be moved by the vacuum pick-up apparatus to be aligned over the lower heat-sink 110.

For example, the upper heat-sink 120 may be aligned such that the plurality of upper electronic devices are disposed within an upper space TS that is defined by the upper plate 121 and the plurality of second side walls 123 of the upper heat-sink 120. The upper heat-sink 120 may be aligned such that the plurality of corresponding second side walls 123 of the upper heat-sink 120 and the plurality of corresponding first side walls 113 of the lower heat-sink 110 are engaged with each other.

The second intermediate member 220 of the intermediate member 200 may be provided to fill or substantially fill a gap between the upper heat-sink 120 and the plurality of upper electronic devices 20, 30a, 30b, and 40, to more effectively transfer heat generated by the plurality of upper electronic devices 20, 30a, 30b, and 40 to the upper heat-sink 120.

Referring to FIGS. 16 to 17, the upper heat-sink 120 and the lower heat-sink 110 may be integrally coupled by using a plurality of connectors CM (not shown) to complete the memory module 10. Thus, the assembly process of the upper heat-sink 120 and the lower heat-sink 110 may be automated by using the vacuum pick-up apparatus.

The lower heat-sink 110 and the upper heat-sink 120 may be integrally coupled by using the plurality of connectors CM that are respectively disposed at corners of the lower base plate 111 of the lower heat-sink 110 and the upper base plate 121 of the upper heat-sink 120. For example, the plurality of connectors may include a plurality of fastening screws, bonding adhesives, etc.

Referring to FIG. 18, the memory module 10 may be moved to an inspection process for the completed memory module 10 by using the vacuum nozzle VN of the vacuum pick-up apparatus.

As mentioned above, in the method of manufacturing the memory module 10, the upper heat-sink 120 may be moved by using the vacuum pick-up apparatus. Further, the memory module 10 may be moved to the inspection process for the memory module 10 by using the vacuum pick-up apparatus.

Accordingly, a nozzle of the vacuum pick-up apparatus may adsorb the upper surfaces of the plurality of adsorption work-pads, so automated assembly process may be possible by using the vacuum pick-up apparatus.

Hereinafter, a memory module in accordance with example embodiments will be described.

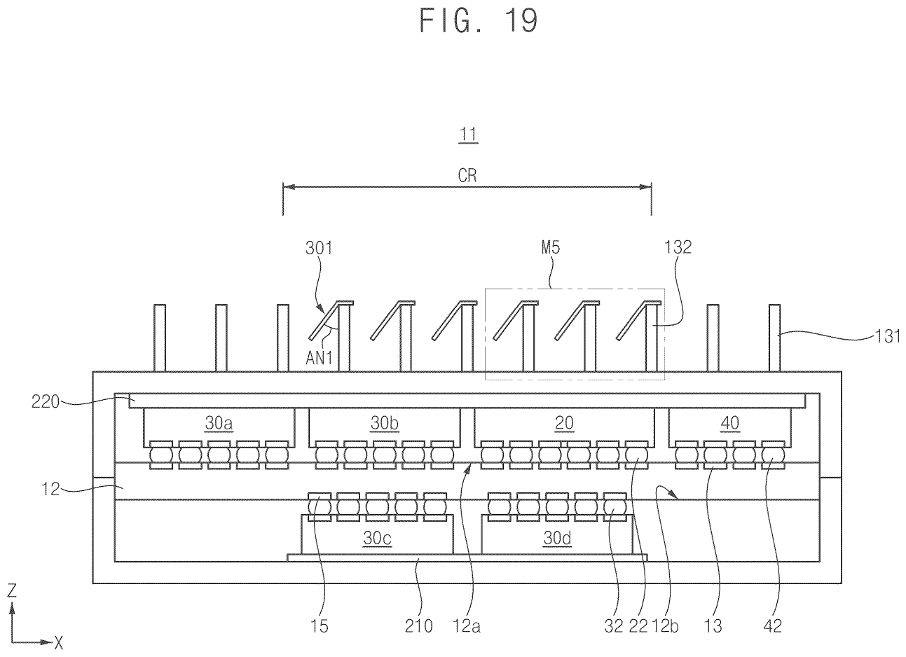

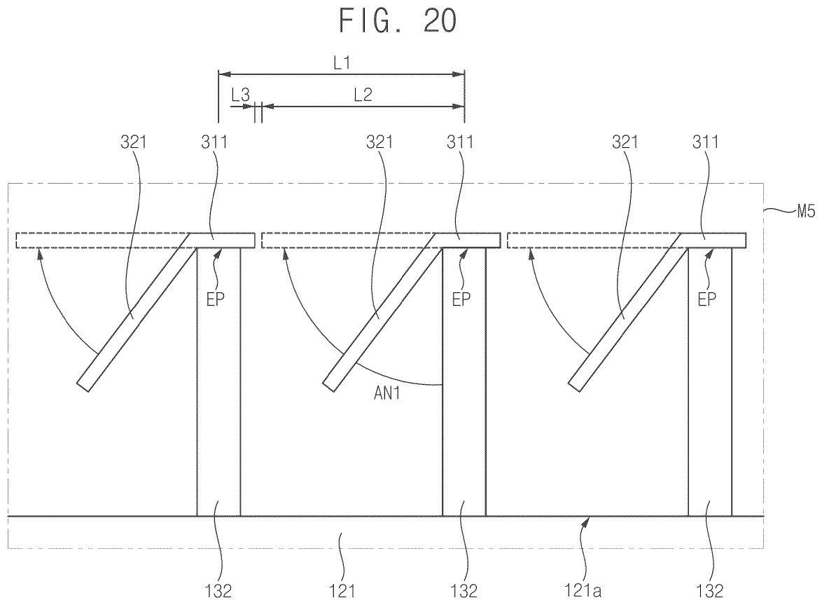

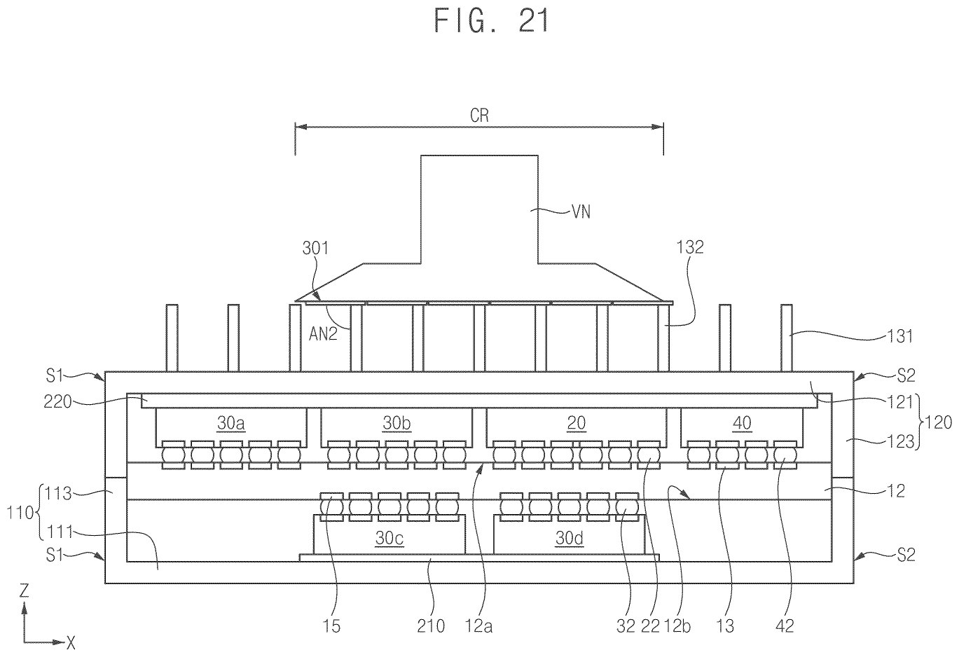

FIG. 19 is a cross-sectional view illustrating a memory module in accordance with example embodiments. FIG. 20 is an enlarged view illustrating portion ‘M5’ in FIG. 19. FIG. 21 is a cross-sectional view illustrating a memory module in accordance with example embodiments.

Referring to FIGS. 19 to 21, a memory module 11 may include a module substrate 12, a plurality of upper electronic devices 20, 30a, 30b, and 40 mounted on the module substrate 12, a plurality of lower electronic devices 30c and 30d mounted on the module substrate 12, a heat sink 100 having a heat-sink body 110 and 120 that surrounds the plurality of upper electronic devices 20, 30a, 30b, and 40 and the plurality of lower electronic devices 30c, 30d to dissipate heat and a plurality of heat dissipating fins 130 that are disposed on an upper surface of the heat-sink body to be spaced apart from each other, and a plurality of adsorption work-pads 301 disposed respectively on end portions of the plurality of heat dissipating fins 130. Additionally, the memory module 11 may further include an intermediate member 200 respectively disposed between the heat-sink body 110 and 120 and the plurality of upper electronic devices 20, 30a, 30b, 40 and between the heat-sink body 110 and 120 and the plurality of lower electronic devices 30c, 30d. Additionally, the memory module 11 may further include a plurality of conductive connection members 22, 32, and 42 respectively disposed between the module substrate 12 and the plurality of upper electronic devices 20, 30a, 30b, 40 and between the module substrate 12 and the plurality of lower electronic devices 30c and 30d.

The memory module 11 may be substantially the same or similar to the memory module 10 described with reference to FIGS. 1 to 4, except for the plurality of adsorption work-pads 301. Accordingly, same devices may be denoted by the same reference numerals and repetitive descriptions of the same devices may be omitted.

In example embodiments, each of the plurality of adsorption work-pads 301 may include a hinge portion 311 that is disposed on each of the plurality of central heat dissipating fins 132 provided on the central region CR of the upper base plate 121 and is bonded (or secured) to an upper surface of each of the plurality of central heat dissipating fins 132 and a folding portion 321 that extends from the hinge portion 311 in the first direction (X direction) and foldable by a certain angle relative to the first direction (X direction) about (or at) the hinge portion 311.

For example, the plurality of adsorption work-pads may be structures configured to provide a contact surface to which a vacuum nozzle of a vacuum pick-up apparatus is attached when the memory module is picked up and moved by using the vacuum pick-up apparatus. The plurality of adsorption work-pads may be structures configured to expose a portion of the upper surface of the heat sink 100 to more effectively dissipate heat generated within the memory module.

For example, the hinge portion and the folding portion may serve as a pad when it comes into contact with the vacuum nozzle of the vacuum pick-up apparatus. For example, a portion of the hinge portion in contact with the vacuum nozzle may serve as a hinge pad. Additionally, a portion of the folding portion in contact with the vacuum nozzle may serve as a folding pad.

For example, the plurality of adsorption work-pads 301 may include a flexible thermal interface material (flexible TIM). The plurality of adsorption work-pads may include a polymer resin, aluminum oxide (Al₂O₃), silicon carbide (SiC), etc.

The plurality of adsorption work-pads 301 may be disposed on end portions of the plurality of central heat dissipating fins 132 to extend in the second direction (Y direction), respectively.

For example, the folding portion 321 of each of the plurality of adsorption work-pads 301 may extend from end portion of each of the plurality of heat central dissipating fins 132 toward the upper surface 121a of the upper base plate 121.

The folding portion 321 of each of the plurality of adsorption work-pads 301 may be disposed on end portions of the plurality of central heat dissipating fins 132 to be fordable along a circumferential direction with respect to the end portion. For example, the folding portion 321 of each of the plurality of adsorption work-pads 301 may have be foldable to have a first angle AN1 with respect to a vertical extension direction of the central heat dissipating fin. The folding portion 321 of each of the plurality of adsorption work-pads 301 may be unfolded along the circumferential direction about (or at) the end portion of the central heat dissipating fin to have a second angle AN2 greater than the first angle AN1 with respect to the vertical extension direction of the central heat dissipating fin.

For example, in case that no external force is applied to the folding portion 321 of each of the plurality of adsorption work-pads 301, the first angle AN1 of the folding portion 321 may have an acute angle. For example, the first angle AN1 may be about or exactly 45 degrees. Thus, the plurality of adsorption work-pads 301 may sufficiently expose the upper surface 121a of the upper base plate 121 of the upper heat-sink 120 to efficiently allow airflow in contact with the upper surface 121a, to thereby more effectively dissipate heat generated inside the memory module.

In addition, in case that the external force is applied to the folding portion 321 of each of the plurality of adsorption work-pads 301, the folding portion 321 may be unfolded to have the second angle AN2 greater than the first angle AN1. For example, the second angle AN2 of the folding portion 321 in an unfolded state may be about or exactly 90 degrees. For example, after positioning the vacuum nozzle VN of the vacuum pick-up apparatus on the plurality of adsorption work-pads 301, vacuum pressure may be applied to the vacuum nozzle VN to unfold folding portions of the plurality of adsorption work-pads 301 such that folding portions of the plurality of adsorption work-pads 301 are adsorbed to a suction surface of the vacuum nozzle VN of the vacuum pick-up apparatus. Accordingly, the plurality of adsorption work-pads 301 may provide a region NR to be in contact with the vacuum nozzle VN, so that the vacuum pick-up apparatus picks up and transfer the memory module.

A length of each of the plurality of adsorption work-pads 301 may be less than a spacing distance between the adjacent heat dissipating fins 130. For example, the spacing distance between the adjacent heat dissipating fins 130 may have a first length L1. The length of each of the plurality of adsorption work-pads 301 may have a second length L2. For example, the first length L1 may be greater than the second length L2.

When the terms “about” or “substantially” are used in this specification in connection with a numerical value, it is intended that the associated numerical value includes a manufacturing or operational tolerance (e.g., ±10%) around the stated numerical value. Moreover, when the words “generally” and “substantially” are used in connection with geometric shapes, it is intended that precision of the geometric shape is not required but that latitude for the shape is within the scope of the disclosure. Further, regardless of whether numerical values or shapes are modified as “about” or “substantially,” it will be understood that these values and shapes should be construed as including a manufacturing or operational tolerance (e.g., ±10%) around the stated numerical values or shapes.

As described herein, any electronic devices and/or portions thereof according to any of the example embodiments may include, may be included in, and/or may be implemented by one or more instances of processing circuitry such as hardware including logic circuits; a hardware/software combination such as a processor executing software; or any combination thereof. For example, the processing circuitry more specifically may include, but is not limited to, a central processing unit (CPU), an arithmetic logic unit (ALU), a graphics processing unit (GPU), an application processor (AP), a digital signal processor (DSP), a microcomputer, a field programmable gate array (FPGA), and programmable logic unit, a microprocessor, application-specific integrated circuit (ASIC), a neural network processing unit (NPU), an Electronic Control Unit (ECU), an Image Signal Processor (ISP), and the like. In some example embodiments, the processing circuitry may include a non-transitory computer readable storage device (e.g., a memory), for example a DRAM device, storing a program of instructions, and a processor (e.g., CPU) configured to execute the program of instructions to implement the functionality and/or methods performed by some or all of any devices, systems, modules, units, controllers, circuits, architectures, and/or portions thereof according to any of the example embodiments, and/or any portions thereof.

The foregoing is illustrative of example embodiments and is not to be construed as limiting thereof. Although a few example embodiments have been described, those skilled in the art will readily appreciate that many modifications are possible in example embodiments without materially departing from the novel teachings and advantages of the present inventions. Accordingly, all such modifications are intended to be included within the scope of example embodiments as defined in the claims. The memory module may include semiconductor devices such as logic devices or memory devices.

The memory module may include logic devices such as central processing units (CPUs), main processing units (MPUs), or application processors (APs), or the like, and volatile memory devices such as DRAM devices, HBM devices, or non-volatile memory devices such as flash memory devices, PRAM devices, MRAM devices, ReRAM devices, or the like.

What is claimed is:

1. A memory module, comprising:
a module substrate having a first surface and a second surface opposite to the first surface, the module substrate extending in a first direction;
a plurality of electronic devices mounted on the first surface of the module substrate;
a heat sink thermally coupled with the first surface of the module substrate, the heat sink including a base plate on the plurality of electronic devices and a plurality of heat dissipating fins on the base plate to be spaced apart from each other along the first direction, each of the plurality of heat dissipating fins extending in a second direction different from the first direction; and
a plurality of adsorption work-pads respectively on a plurality of central heat dissipating fins among the plurality of heat dissipating fins on a central region of the base plate, each of the plurality of adsorption work-pads having a hinge portion secured to an end portion of the central heat dissipating fins and a folding portion extending from the hinge portion in the first direction and foldable by a certain angle relative to the hinge portion.

2. The memory module of claim 1, further comprising:
an intermediate member configured to transfer heat, the intermediate member between the base plate and the plurality of electronic devices.

3. The memory module of claim 1, wherein each of the plurality of adsorption work-pads extends from an end portion of each of the plurality of central heat dissipating fins toward an upper surface of the base plate.

4. The memory module of claim 3, wherein each of the plurality of adsorption work-pads has a first angle relative to a vertical extension direction of the central heat dissipating fin.

5. The memory module of claim 4, wherein each of the plurality of adsorption work-pads is on the end portion of the central heat dissipating fin such that the adsorption work-pad is foldable along a circumferential direction at the end portion to have a second angle that is greater than the first angle with respect to the vertical extension direction of the central heat dissipating fin.

6. The memory module of claim 5, wherein the first angle is 45 degrees, the second angle is 90 degrees.

7. The memory module of claim 1, wherein the plurality of adsorption work-pads include polymer resin, aluminum oxide (Al₂O₃) or silicon carbide (SiC).

8. The memory module of claim 1, wherein the plurality of adsorption work-pads alternatively on the plurality of central heat dissipating fins, each of the plurality of adsorption work-pads including a first foldable pad and a second fordable pad that respectively extend in opposite directions from the end portion of the central heat dissipating fin toward an upper surface of the base plate.

9. The memory module of claim 8, wherein the first foldable pad and the second foldable pad have a first angle with respect to a vertical extension direction of the central heat dissipating fin.

10. The memory module of claim 9, wherein the first foldable pad and the second foldable pad are on the end portion of the central heat dissipating fin such that the adsorption work-pad is foldable along a circumferential direction at the end portion to have a second angle that is greater than the first angle with respect to the vertical extension direction of the central heat dissipating fin.

11. A memory module, comprising:
a module substrate having a first surface and a second surface opposite to the first surface, the module substrate extending in a first direction;
a plurality of electronic devices mounted on the first surface of the module substrate;
a heat sink thermally coupled with the first surface of the module substrate, the heat sink including a base plate on the plurality of electronic devices and a plurality of central heat dissipating fins on a central region of an upper surface of the base plate, the base plate including first and second side portions extending in a second direction perpendicular the first direction and third and fourth side portions extending in the first direction, and the heat sink extending between the third side portion and the fourth side portion; and
a plurality of adsorption work-pads respectively on end portions of the plurality of central heat dissipating fins, each of the plurality of adsorption work-pads having a hinge portion fastened to the end portion of the central heat dissipating fin and a folding portion extending from the hinge portion in the first direction and foldable by a certain angle relative to the first direction centered on the hinge portion.

12. The memory module of claim 11, further comprising:
an intermediate member configured to transfer heat, the intermediate member between the base plate and the plurality of electronic devices.

13. The memory module of claim 12, wherein the plurality of adsorption work-pads include polymer resin, aluminum oxide (Al₂O₃) or silicon carbide (SiC).

14. The memory module of claim 11, wherein each of the plurality of adsorption work-pads extends from the end portion of each of the plurality of central heat dissipating fins toward an upper surface of the base plate, each of the plurality of adsorption work-pads having a first angle relative to a vertical extension direction of the central heat dissipating fin.

15. The memory module of claim 14, wherein each of the plurality of adsorption work-pads is on the end portion of the central heat dissipating fin such that the adsorption work-pad is foldable along a circumferential direction at the end portion to have a second angle that is greater than the first angle with respect to the vertical extension direction of the central heat dissipating fin.

16. The memory module of claim 15, wherein the first angle is 45 degrees, the second angle is 90 degrees.

17. The memory module of claim 11, wherein the plurality of adsorption work-pads are alternatively on the plurality of central heat dissipating fins, each of the plurality of adsorption work-pads including a first foldable pad and a second fordable pad that respectively extend in opposite directions from the end portion of the central heat dissipating fin toward an upper surface of the base plate.

18. The memory module of claim 17, wherein the first foldable pad and the second foldable pad have a first angle with respect to a vertical extension direction of the central heat dissipating fin.

19. The memory module of claim 18, wherein the first foldable pad and the second foldable pad are on the end portion of the central heat dissipating fin such that the adsorption work-pad is foldable along a circumferential direction at the end portion to have a second angle that is greater than the first angle with respect to the vertical extension direction of the central heat dissipating fin.

20. A memory module, comprising:
a module substrate having a first surface and a second surface opposite to the first surface, the module substrate extending in a first direction;
a plurality of electronic devices mounted on the first surface of the module substrate via a plurality of connection members;
a base plate coupled with the first surface of the module substrate and on the plurality of electronic devices, the base plate having first and second side portions extending in a second direction perpendicular the first direction and third and fourth side portion extending in the first direction;
a plurality of central heat dissipating fins on a central region of an upper surface of the base plate and extending between the third side portion and the fourth side portion;
an intermediate member configured to transfer heat and between the base plate and the plurality of electronic devices; and
a plurality of adsorption work-pads alternatively on end portions of the plurality of central heat dissipating fins, each of plurality of adsorption work-pads having a hinge portion bonded to an upper surface of the central heat dissipating fin and extending in the second direction, and a folding portion extending from the hinge portion along the first direction and foldable by a certain angle relative to the first direction centered on the hinge portion.
